(19) United States
(12) Patent Application Publication
(10) Pub. No.: US 2016/0282065 A1
(43) Pub. Date: Sep. 29, 2016

(54) HEAT SINK, COOLING STRUCTURE, AND APPARATUS

(71) Applicant: NEC Corporation, Tokyo (JP)

(72) Inventor: Tomoyuki MITSUI, Tokyo (JP)

(73) Assignee: NEC Corporation

(21) Appl. No.: 15/072,539

(22) Filed: Mar. 17, 2016

(30) Foreign Application Priority Data
Mar. 23, 2015 (JP) 2015-059700

(51) Int. Cl. F28F 13/06; H01L 23/467; F28F 3/02

(52) U.S. Cl. CPC F28F 13/06; F28F 3/02; H01L 23/467

(57) ABSTRACT

An object of the present invention is to reduce imbalance of an airflow volume passed through each fin even when a heat sink is brought close to an air blowing part. In order to achieve the object, the heat sink according to the present invention includes a flat plate shaped base part and a plurality of fins erected on one surface of the base part, and at least part of the plurality of fins includes an air guide region guiding air to at least an adjacent fin, at a location where air flows in.

This application is based upon and claims the benefit of priority from Japanese Patent Application No. 2015-059700, filed on Mar. 23, 2015, the disclosure of which is incorporated herein in its entirety by reference.

### TECHNICAL FIELD

The present invention relates to a heat sink, a cooling structure, and an apparatus.

### BACKGROUND ART

In recent years, performance of an apparatus (such as an electronic apparatus) including a personal computer has been increasing. Calorific values of a heating element, such as a CPU mounted on a personal computer, a peripheral integrated circuit of the CPU, and a power circuit, tend to increase accordingly. “CPU” is an abbreviation for “central processing unit.” Thus, a technology of radiating heat generated by a heating element is required for an electronic apparatus. As a technology of radiating heat generated by a heating element, a technology using a heat sink is generally known. The heat sink is provided in thermal contact with a heating element. Consequently, heat generated by the heating element is transferred to the heat sink and the transferred heat is radiated by the heat sink.

As for such a technology of radiating heat generated by a heating element using a heat sink, a technology, for example, related to a semiconductor cooling structure is disclosed in PTL 1. The technology described in PTL 1 includes a plate fin type heat sink formed to erect a plurality of fins in parallel on a base surface. The technology described in PTL 1 further sends air in an extending direction of the fins by use of a fan, and cools the heat sink by feeding air between the respective fins. Thus, the technology described in PTL 1 enhances a radiation effect of a heat sink by cooling the heat sink.

### CITATION LIST

### Patent Literature

[PTL 1] Japanese Patent No. 3030526

### SUMMARY

### Technical Problem

However, in the technology in PTL 1 described above, when an air blowing part (fan) is arranged close to a heat sink, an airflow is blocked by a fin close to the air blowing part in a width direction of the heat sink, and therefore air cannot be sent to a fin distant from the air blowing part.

By use of FIG. 11, a heat sink 940, a cooling structure 930, and an electronic apparatus (apparatus) 900 related to a technology of the present invention will be exemplified and a reason for causing the aforementioned unevenness in heat radiation performance will be described. FIG. 11 is a perspective view illustrating a configuration of the heat sink 940, the cooling structure 930, and the electronic apparatus (apparatus) 900 related to the present invention. A thick arrow illustrated in FIG. 11 is an arrow indicating a flow of air sent from an air blowing part 950.

The electronic apparatus 900 includes a substrate 910, a heating element 920, and the cooling structure 930. The cooling structure 930 includes the heat sink 940 and the air blowing part 950. As exemplified in FIG. 11, a blowing port 951 of the air blowing part 950 is generally located facing part of the heat sink 940 in a width direction instead of across a full width in the width direction. Consequently, while a part of the heat sink 940 close to the blowing port 951 of the air blowing part 950 is able to take in an airflow from the air blowing part 950, a distant part is not able to take in an airflow from the air blowing part 950 because the airflow is blocked by a fin of the heat sink 940. Thus, the heat sink 940 causes imbalance of a passed airflow volume between a part close to the blowing port 951 of the air blowing part 950 and a distant part.

When the heat sink 940 is arranged, for example, apart from the air blowing part 950, the aforementioned problem is solved but a size of the heat sink 940 needs to be reduced when a size of the electronic apparatus 900 is restricted. A case that a size of the electronic apparatus 900 is restricted refers to a case that, for example, a size of a housing is restricted as is the case with a blade server and the like. Thus, heat radiation performance is degraded when a size of the heat sink 940 needs to be reduced. Further, when the heat sink 940 is arranged apart from the air blowing part 950, there is a technical problem that it is difficult to radiate heat of a heating element located in proximity to the air blowing part 950.

For such a reason, in aforementioned PTL 1, there is a technical problem that bringing a heat sink close to an air blowing part causes imbalance of an airflow volume passed through each fin, and bringing the heat sink apart from a fin restricts a size of the heat sink and a layout of a heating element.

In view of the actual situation described above, an object of the present invention is to provide a heat sink, a cooling structure, and an apparatus capable of reducing imbalance of an airflow volume passed through each fin even when a heat sink is brought close to an air blowing part.

In order to achieve the object described above, a heat sink according to the present invention includes a flat plate shaped base part and a plurality of fins erected on one surface of the base part, and at least part of the plurality of fins includes an air guide region guiding air to at least an adjacent fin, at a location where air flows in.

In order to achieve the object described above, a cooling structure according to the present invention includes the aforementioned heat sink and an air blowing part sending air to the aforementioned heat sink.

In order to achieve the object described above, an apparatus according to the present invention includes the aforementioned cooling structure and a heating element transferring heat to the aforementioned cooling structure.

The present invention is able to reduce imbalance of an airflow volume passed through each fin even when a heat sink is brought close to an air blowing part.

### BRIEF DESCRIPTION OF THE DRAWINGS

FIG. 1 is a perspective view illustrating a configuration of a heat sink, a cooling structure, and an electronic apparatus (apparatus) according to one exemplary embodiment (first exemplary embodiment) of the present invention.

FIG. 2 is an exploded perspective view illustrating a configuration of the heat sink, the cooling structure, and the electronic apparatus (apparatus) according to the one exemplary embodiment (first exemplary embodiment) of the present invention.

FIG. 3 is a plan view illustrating a configuration of the heat sink, the cooling structure, and the electronic apparatus (apparatus) according to the one exemplary embodiment (first exemplary embodiment) of the present invention.

FIG. 4 is a side view illustrating a state viewed from an A direction in FIG. 3.

FIG. 5 is a perspective view illustrating a configuration of a heat sink, a cooling structure, and an electronic apparatus (apparatus) according to another exemplary embodiment (second exemplary embodiment) of the present invention.

FIG. 6 is an exploded perspective view illustrating a configuration of the heat sink, the cooling structure, and the electronic apparatus (apparatus) according to the another exemplary embodiment (second exemplary embodiment) of the present invention.

FIG. 7 is a plan view illustrating a configuration of the heat sink, cooling structure, and the electronic apparatus (apparatus) according to the another exemplary embodiment (second exemplary embodiment) of the present invention.

FIG. 8 is a side view illustrating a state viewed from a B direction in FIG. 7.

FIG. 9 is a perspective view illustrating a configuration of a heat sink, a cooling structure, and an electronic apparatus (apparatus) according to yet another exemplary embodiment (third exemplary embodiment) of the present invention.

FIG. 10 is an exploded perspective view illustrating a configuration of the heat sink, the cooling structure, and the electronic apparatus (apparatus) according to the yet another exemplary embodiment (third exemplary embodiment) of the present invention.

FIG. 11 is a perspective view illustrating a configuration of a heat sink, a cooling structure, and an electronic apparatus (apparatus) related to the present invention.

### EXEMPLARY EMBODIMENT

Exemplary embodiments of the present invention will be described below by use of the drawings.

### First Exemplary Embodiment

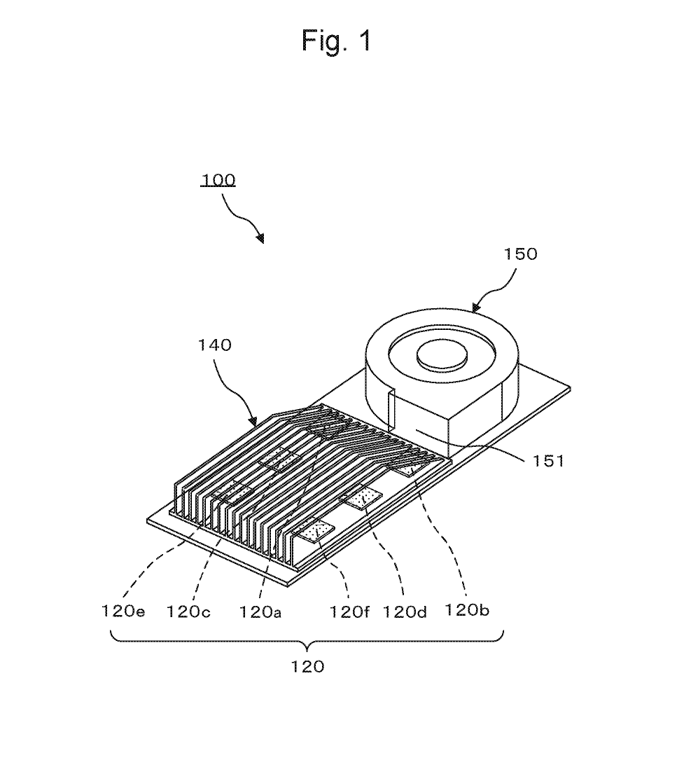

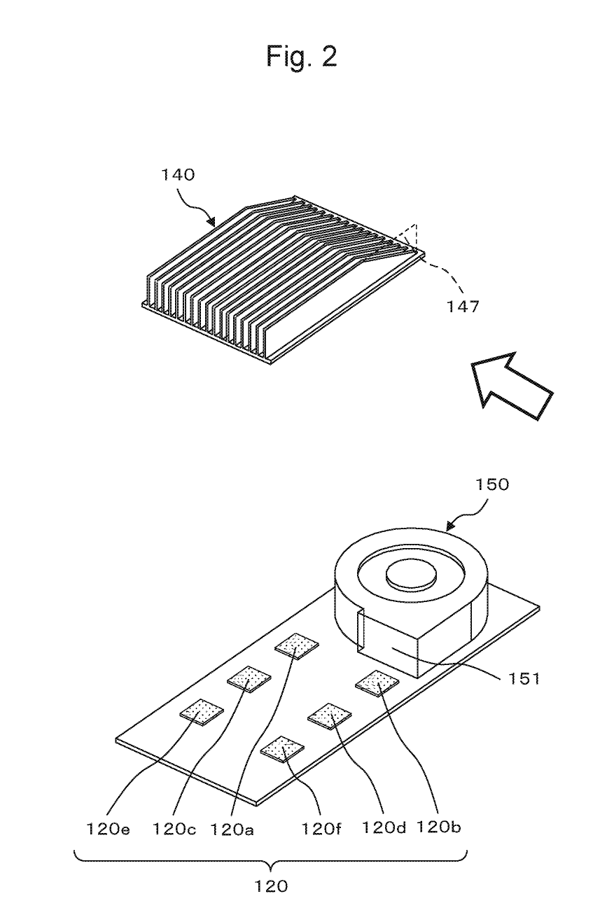

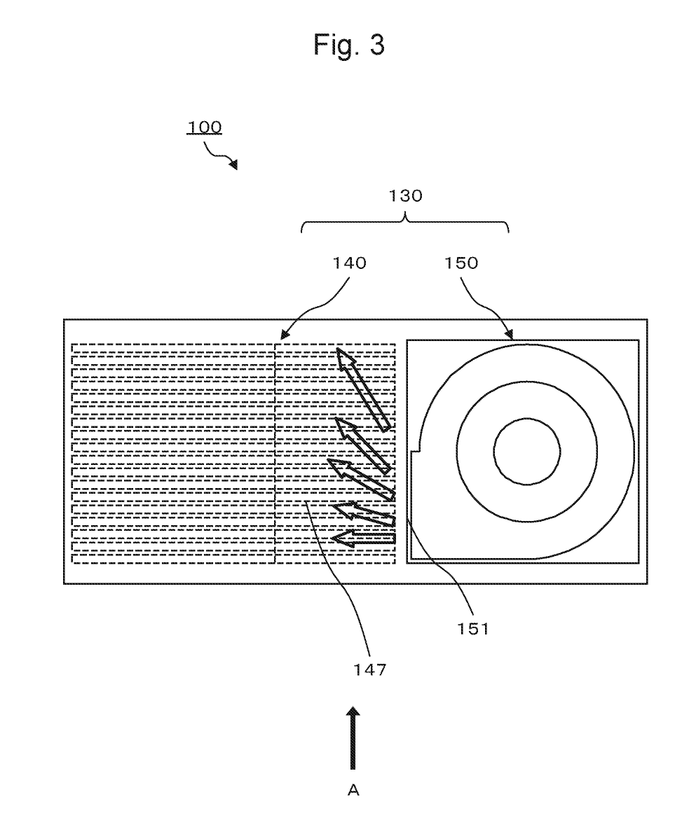

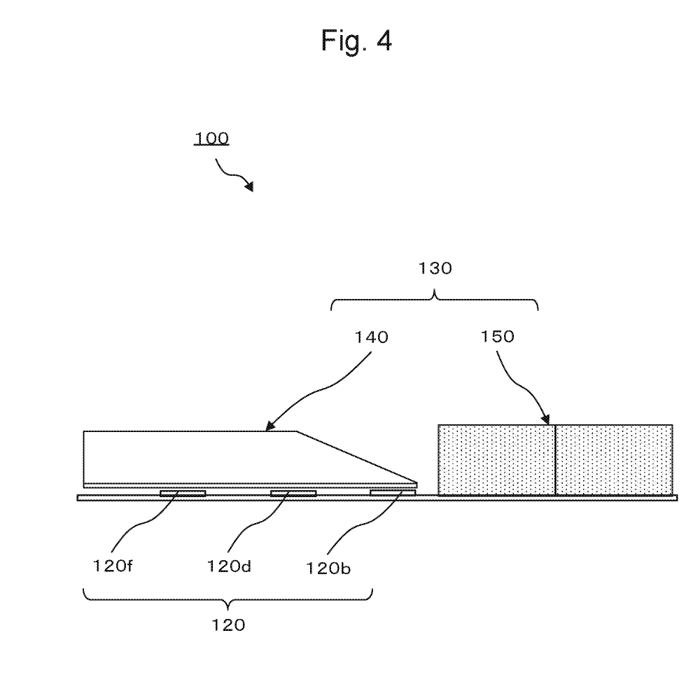

An exemplary embodiment (first exemplary embodiment) of the present invention will be described by use of FIGS. 1 to 4. FIGS. 1 to 3 are respectively a perspective view, an exploded perspective view, and a plan view illustrating a configuration of a heat sink 140, a cooling structure 130, and an electronic apparatus (apparatus) 100 according to the present exemplary embodiment (first exemplary embodiment). FIG. 4 is a side view illustrating a state viewed from an A direction in FIG. 3. A thick arrow illustrated in FIG. 2 indicates a direction of light irradiated to the heat sink 140. Thick arrows illustrated in FIG. 3 are arrows indicating flows of air sent from an air blowing part 150.

The electronic apparatus 100 includes a heating element 120 and the cooling structure 130. The heating element 120, being a known technology, and therefore description thereof being kept brief rather than specific, is, for example, an integrated circuit element such as a CPU, an IC, an LSI, and an MPU. The heating element 120 generates heat when in operation. In order to radiate heat generated by the heating element 120, the heat sink 140 in the cooling structure 130 is mounted on the heating element 120. “IC” is an abbreviation for “integrated circuit.” “LSI” is an abbreviation for “large scale integration.” “CPU” is an abbreviation for “central processing unit.” “MPU” is an abbreviation for “micro processing unit.”

The cooling structure 130 includes the heat sink 140 and the air blowing part 150. The heat sink 140 includes a flat plate shaped base part. Further, the heat sink 140 includes a plurality of fins erected on one surface of the base part. At least part of the plurality of fins includes an air guide region 147 guiding air to at least an adjacent fin, at a location receiving air.

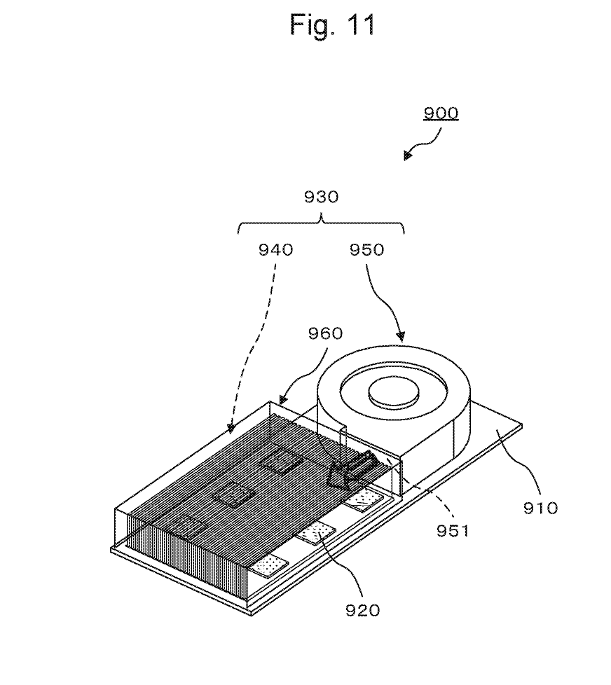

As seen in the heat sink 940, the cooling structure 930, and the electronic apparatus 900 related to the present exemplary embodiment exemplified by use of FIG. 11, when the heat sink 940 is brought in proximity to the air blowing part 950, an airflow is blocked by a fin close to the blowing port 951 of the heat sink 940, and therefore air cannot be sent to a fin distant from the blowing port 951. Consequently, the related technology causes unevenness in heat radiation performance of the heat sink 940.

By contrast, as described above, the heat sink 140 according to the present exemplary embodiment includes the air guide region 147 guiding air to at least an adjacent fin, at a location receiving air on at least part of a plurality of fins. Consequently, even when the heat sink 140 is brought close to a blowing port 151 of the air blowing part 150, the heat sink 140 is capable of securing space for feeding air sent from the blowing port 151 of the air blowing part 150 in a width direction of the heat sink 140.

Therefore, the heat sink 140 according to the present exemplary embodiment is capable of reducing temperature difference between respective fins of the heat sink 140 even when the heat sink 140 is brought close to the air blowing part 150.

Similarly, the cooling structure 130 according to the present exemplary embodiment is capable of reducing imbalance of an airflow volume passed through the heat sink 140 even when the heat sink 140 is brought close to the blowing port 151 of the air blowing part 150. Similarly, the electronic apparatus 100 according to the present exemplary embodiment is capable of reducing imbalance of an airflow volume passed through the heat sink 140 even when the heat sink 140 is brought close to the air blowing part 150.

### Second Exemplary Embodiment

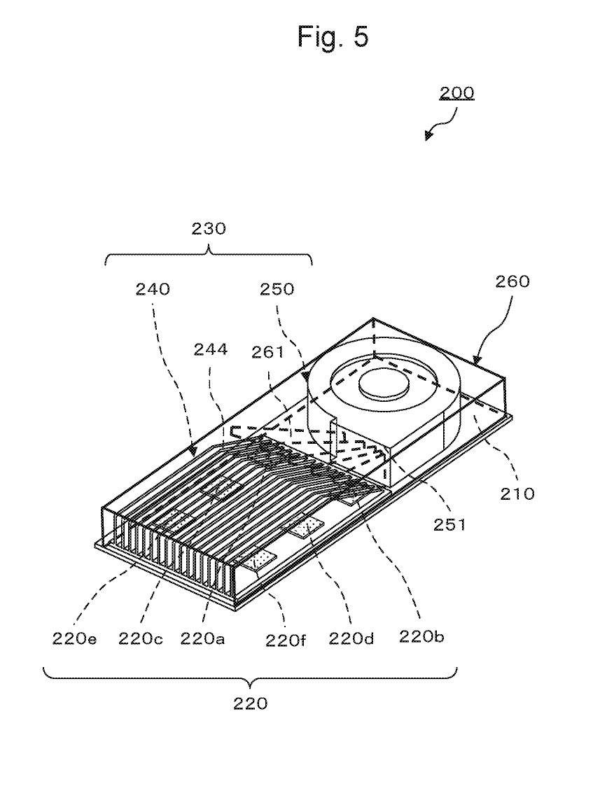

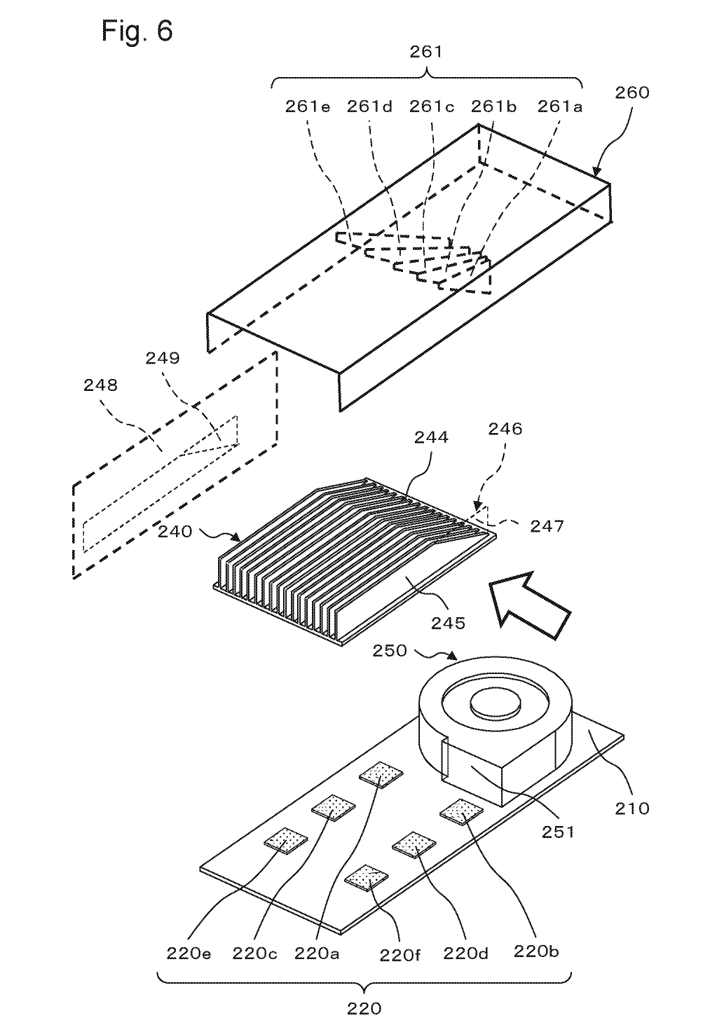

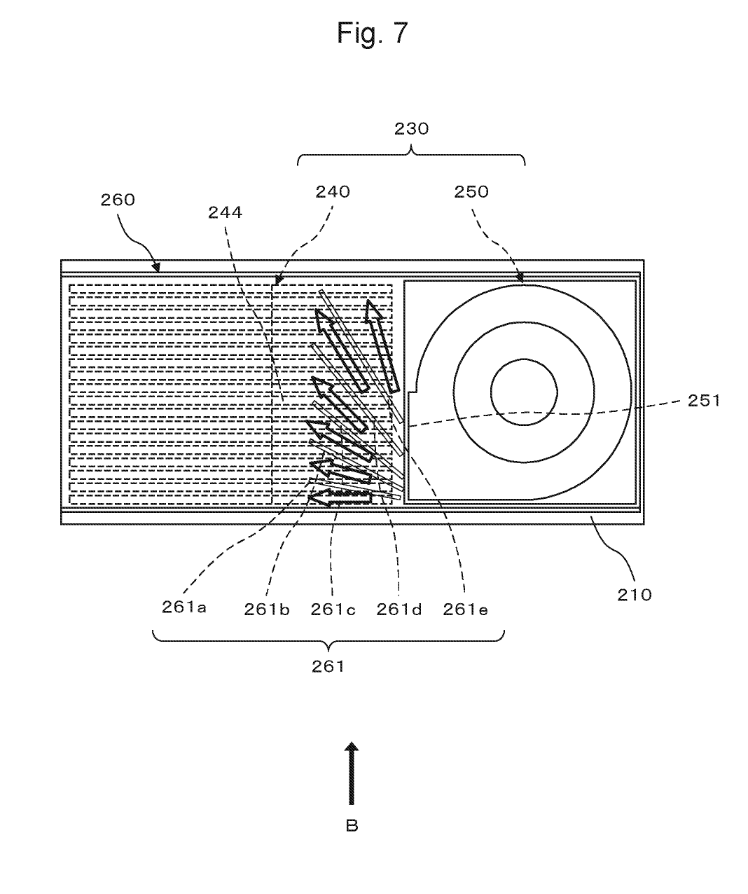

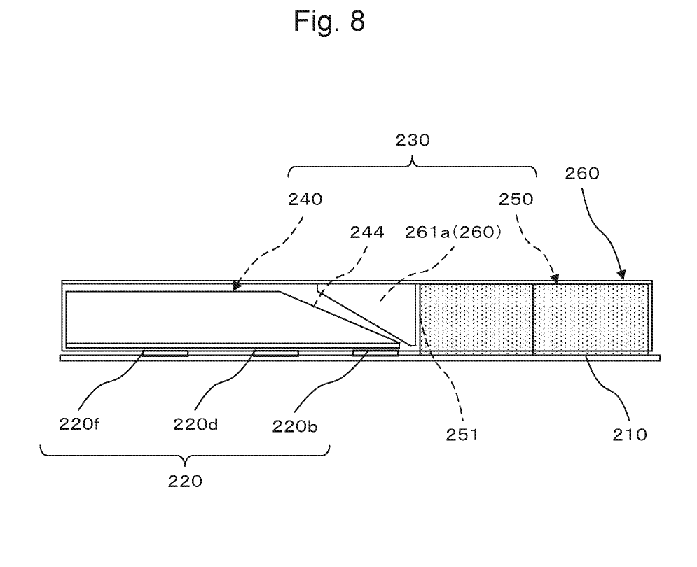

Another exemplary embodiment (second exemplary embodiment) of the present invention will be described by use of FIGS. 5 to 8. FIGS. 5 to 7 are respectively a perspective view, an exploded perspective view, and a plan view illustrating a configuration of a heat sink 240, a cooling structure 230, and an electronic apparatus (apparatus) 200 according to the present exemplary embodiment (second exemplary embodiment). FIG. 8 is a side view illustrating a state viewed from a B direction in FIG. 7. A thick arrow illustrated in FIG. 7 is an arrow indicating a flow of air sent from an air blowing part 250.

The electronic apparatus 200 includes a substrate 210, a heating element 220, a cooling structure 230, and a housing 260. The substrate 210, being a known technology, and therefore description thereof being kept brief rather than specific, is formed in a plate shape by use of phenolic resin, epoxy resin, and the like. Further, the heating element 220 is arranged on a surface of the substrate 210 formed in a plate shape.

The heating element 220, being a known technology, and therefore description thereof being kept brief rather than specific, is, for example, an integrated circuit element such as a CPU, an IC, an LSI, and an MPU. The heating element 220 generates heat when in operation. In order to radiate heat generated by the heating element 220, the heat sink 240 in the cooling structure 230 is mounted on the heating element 220.

The cooling structure 230 includes the heat sink 240 and the air blowing part 250. The heat sink 240 is formed to include a plurality of fins erected at predetermined intervals on one surface of a base part formed in a flat plate shape, and ventilates air sent from the air blowing part between the plurality of fins to radiate heat generated from the heating element 220. The heat sink 240 is formed by use of a metal with high thermal conductivity such as aluminum, iron, and copper.

Citing an example of the heat sink 240, the heat sink 240 is a plate fin type and includes a base part and a plurality of plate fins with the plurality of plate fins erected on the base part. The plate fin type heat sink 240 extends the plurality of plate fins along a blowing direction of air from the air blowing part 250. Consequently, when the air blowing part 250 sends air to the heat sink 240, an airflow passes between the respective plate fins, allowing for cooling of the entire heat sink 240. Thus, the heat sink 240 enhances an effect of radiating heat generated by the heating element 220. The heat sink 240 according to the present exemplary embodiment, being a plate fin type as described above, is not limited to the plate fin type and may be a pin fin type or the like.

Each of the plurality of fins of the heat sink 240 according to the present exemplary embodiment includes a region 247 which is not included in a planar shape 245 of the fin and included in a rectangle 246 having a minimum area including the planar shape 245, and an orthogonal projection 249 of each fin on a predetermined plane 248 shares a common part. The heat sink 240 will be described later.

The air blowing part 250, being a known technology, and therefore description thereof being kept brief rather than specific, is, for example, an axial fan and a blower fan. The air blowing part 250 is arranged at a location allowing for sending air in an extending direction of the fins of the heat sink 240. The housing 260 is arranged on a circumference of the heat sink 240 and the air blowing part 250 constituting the cooling structure 230 in order to suppress leakage of air sent to the heat sink 240 from the air blowing part 250.

The housing 260 is formed in a tunnel shape having space inside. Further, the housing 260 is arranged so as to cover the heat sink 240 and the air blowing part 250. Thus, the housing 260 suppresses leakage of air sent from the air blowing part 250 as described above. A straightening plate 261 is arranged on an inner surface of the housing 260 according to the present exemplary embodiment. The straightening plate 261 will be described later along with a defining part 244 of the heat sink 240.

The cooling structure 230 according to the present exemplary embodiment brings the heat sink 240 in proximity to the air blowing part 250. Thus, the cooling structure 230 is capable of radiating heat generated from a first heating element 220a or a second heating element 220b located close to the air blowing part 250 by bringing the heat sink 240 in proximity to the air blowing part 250.

As seen in the heat sink 940, the cooling structure 930, and the electronic apparatus 900 related to the present exemplary embodiment exemplified by use of FIG. 11, when the heat sink 940 is brought in proximity of the air blowing part 950, air cannot be sent evenly to each fin of the heat sink 940. Consequently, the related technology causes unevenness in heat radiation performance of the heat sink 940.

By contrast, the cooling structure 230 according to the present exemplary embodiment has a configuration capable of sending air to each fin of the heat sink 240 even when the heat sink 240 is brought close to the air blowing part 250. Details will be described below. Each of the plurality of fins of the heat sink 240 according to the present exemplary embodiment includes a notched part 246 on the air blowing part 250 side. The plurality of notched parts 246 according to the present exemplary embodiment are provided at a same location in a same shape on the heat sink 240. Consequently, every notched part 246 overlaps one another when viewed from a width direction of the heat sink 240. Thus, a triangular pyramid shaped space appears at a notched part of the heat sink 240 and becomes the air guide region 247. The plurality of notched parts 246 are not limited to be provided at a same location in a same shape, and may be arranged so as to overlap one another at least partially when viewed from a width direction of the heat sink 240. Thus, by each fin having the region 247, a ventilation region ventilating air sent from the air blowing part 250 in a width direction of the heat sink 240 is defined between the heat sink 240 and the air blowing part 250. Consequently, air sent from the air blowing part 250 is fed to each fin of the heat sink 240 through the ventilation region.

In order to define the aforementioned region 247, a corner of each fin of the heat sink 240 according to the present exemplary embodiment is obliquely notched. Consequently, an inclined plane 244 is formed on a surface of the heat sink 240 facing the air blowing part 250. While the inclined plane 244 is adopted by the present exemplary embodiment, another type of plane defining an air guide region between the heat sink 240 and the air blowing part 250, such as a plane formed by notching a corner of a fin in an arcuate shape, may be adopted without limiting to the inclined plane 244. The region may be formed by notching an entire fin leaving the base part. Further, the region may be formed by notching part of a fin in a recessed shape. Further, the region may be formed by providing an air opening on part of a fin. Further, the region may be formed by gradually increasing a height of a fin from a location close to the air blowing part 250 toward a distant location.

Further, in order to more securely send air to a full width of the heat sink 240 in a width direction, the cooling structure 230 according to the present exemplary embodiment includes a plurality of straightening plates 261 in the aforementioned air guide region. Specifically, the plurality of straightening plates 261 are mounted on an inner surface of the housing 260 and are perpendicularly extended from the inner surface. Further, the plurality of straightening plates 261 are radially extended toward the heat sink 240 from a blowing port 251 of the air blowing part 250. Straightening plates 261 illustrated in FIG. 7 are hereinafter referred to as a first straightening plate 261a, a second straightening plate 261b, a third straightening plate 261c, a fourth straightening plate 261d, and a fifth straightening plate 261e from the lower side toward the upper side.

Respective straightening plates are arranged in a manner that respective angles made by an opening surface of the blowing port 251 of the air blowing part 250 with the first straightening plate 261a through the fifth straightening plate 261e decrease in this order. Thus, a space of a region demarcated by the straightening plates 261 becomes large toward the fifth straightening plate 261e side. Consequently, in regions demarcated by the straightening plates 261, an airflow volume that can be taken in from the air blowing part 250 becomes large toward the fifth straightening plate 261e side. Thus, by adjusting an airflow volume that can be taken in, balance of air sent from the air blowing part 250 between a location close to the blowing port 251 and a distant location is adjusted. Therefore, air sent from the air blowing part 250 can be fed to a full width of the heat sink 240 in a width direction. Furthermore, by the straightening plates 261, air sent from the air blowing part 250 can be supplied to the entire heat sink 240 in a well-balanced manner.

Further, the plurality of straightening plates 261 are formed to have respective areas increased from the first straightening plate 261a toward the fifth straightening plate 261e. Thus, respective areas of the first straightening plate 261a through the fifth straightening plate 261e are increased in this order, and therefore air guide regions demarcated by the plurality of straightening plates 261 become larger from a location close to the blowing port 251 toward a distant location. Consequently, in the regions demarcated by the straightening plates 261, an airflow volume that can be taken in from the air blowing part 250 becomes larger toward the fifth straightening plate 261e side. Thus, balance of air sent from the air blowing part 250 between a location close to the blowing port 251 and a distant location is adjusted.

Further, respective intervals between the plurality of straightening plates 261 at the blowing port 251 become shorter from a location close to the heat sink 240 in a width direction toward a distant location. Thus, by varying intervals at the blowing port 251 between the plurality of straightening plates 261, areas of the blowing port 251 demarcated by the plurality of straightening plates 261 are varied. Consequently, airflow speed passing the blowing port 251 can be increased from a location close to the heat sink 240 in a width direction toward a distant location. Thus, balance of air sent from the air blowing part 250 between a location close to the blowing port 251 and a distant location is adjusted.

As described above, the heat sink 240 according to the present exemplary embodiment is capable of ventilating air sent from the air blowing part 250 over the entire main body even when the main body is brought close to the air blowing part 250, and also capable of suppressing imbalance of air sent from the air blowing part 250.

Similarly, the cooling structure 230 according to the present exemplary embodiment is capable of ventilating air sent from the air blowing part 250 over the entire heat sink 240 even when the heat sink 240 is brought close to the air blowing part 250. Therefore, the cooling structure 230 is capable of suppressing imbalance of air sent from the air blowing part 250.

Similarly, the electronic apparatus 200 according to the present exemplary embodiment is capable of ventilating air sent from the air blowing part 250 over the entire heat sink 240 even when the heat sink 240 is brought close to the air blowing part 250. Therefore, the electronic apparatus 200 is capable of suppressing imbalance of air sent from the air blowing part 250.

As an example of the electronic apparatus 200 according to the present exemplary embodiment, the electronic apparatus 200 is a card in conformity with the PCIE standard. A card size in conformity with the PCIE standard generally includes full-size, short-size, and low-profile types. The card size of the full-size type in conformity with the PCIE standard is defined as 107 mm in height and 312 mm in length. Further, the short-size type is defined as 107 mm in height and 173 mm in length. “PCIE” is an abbreviation for “Peripheral Component Interconnect Express.”

### Third Exemplary Embodiment

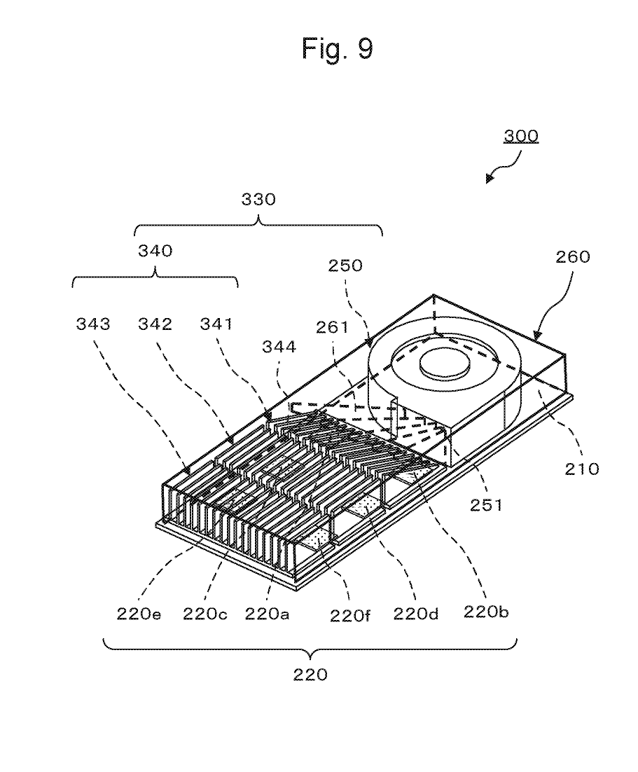

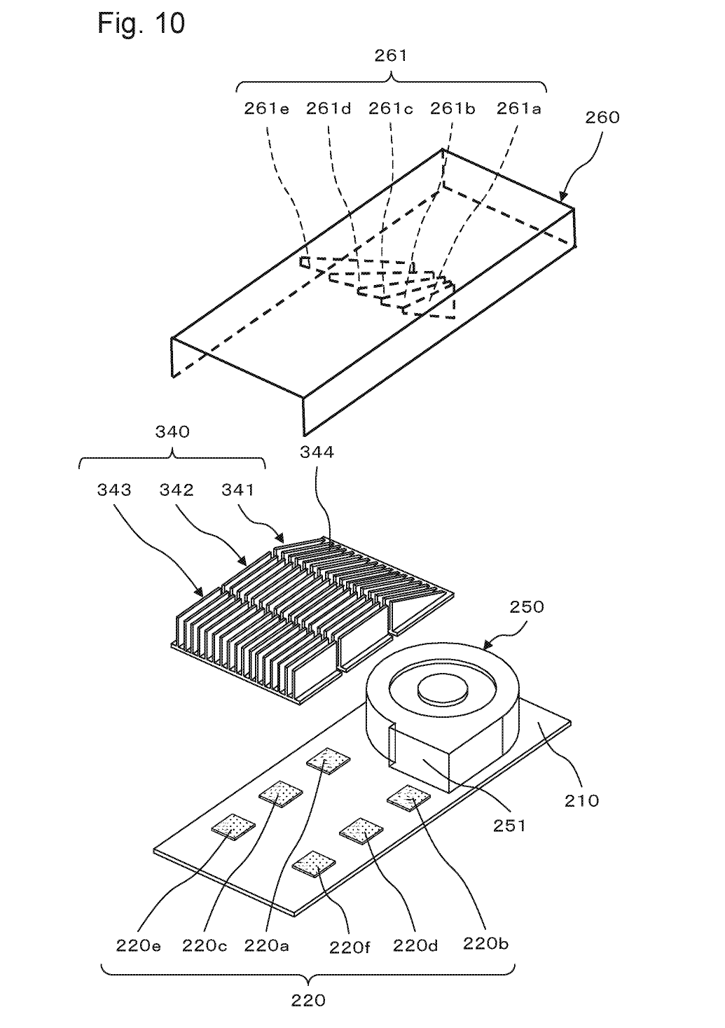

Yet another exemplary embodiment (third exemplary embodiment) of the present invention will be described by use of FIGS. 9 and 10. FIGS. 9 and 10 are respectively a perspective view and an exploded perspective view illustrating a configuration of a heat sink 340, a cooling structure 330, and an electronic apparatus 300 according to the present exemplary embodiment (third exemplary embodiment).

The heat sink 340 according to the present exemplary embodiment is similar to the heat sink 240 according to the aforementioned second exemplary embodiment except that the heat sink 340 is configured with a first heat sink 341, a second heat sink 342, and a third heat sink 343. Consequently, a same or corresponding sign is given to a part corresponding to the aforementioned second exemplary embodiment and description thereof is omitted.

The heat sink 340 according to the present exemplary embodiment includes the first heat sink 341, the second heat sink 342, and the third heat sink 343. Thus, the heat sink 340 according to the present exemplary embodiment is configured in such a manner that the first heat sink 341, the second heat sink 342, and the third heat sink 343 are independent of one another. Consequently, it is mutually difficult for the heat sink 340 to transfer heat transferred from the heating element 220 to another heat sink 340, and thus heat radiation performance is mutually enhanced.

### REFERENCE SIGNS LIST

100 Electronic apparatus
120 Heating element
130 Cooling structure
140 Heat sink
147 Air guide region
150 Air blowing part

The previous description of embodiments is provided to enable a person skilled in the art to make and use the present invention. Moreover, various modifications to these exemplary embodiments will be readily apparent to those skilled in the art, and the generic principles and specific examples defined herein may be applied to other embodiments without the use of inventive faculty. Therefore, the present invention is not intended to be limited to the exemplary embodiments described herein but is to be accorded the widest scope as defined by the limitations of the claims and equivalents. Further, it is noted that the inventor's intent is to retain all equivalents of the claimed invention even if the claims are amended during prosecution.

1. A heat sink comprising a flat plate shaped base part and
a plurality of fins erected on one surface of the base part, and at least part thereof includes an air guide region guiding air to at least an adjacent fin, at a location where air flows in.

2. The heat sink according to claim 1, wherein the air guide region is formed by obliquely notching a corner of a fin.

3. The heat sink according to claim 1, wherein the air guide region is formed by notching a corner of a fin in an arcuate shape.

4. A cooling structure comprising:
a heat sink including
a flat plate shaped base part and
a plurality of fins erected on one surface of the base part,
and at least part thereof includes an air guide region guiding air to at least an adjacent fin, at a location where air flows in; and
an air blowing part sending air to the heat sink.

5. The cooling structure according to claim 4, wherein a straightening plate guiding air from the air blowing part toward the heat sink is arranged in the air guide region.

6. The cooling structure according to claim 5 further comprising a plurality of the straightening plates, wherein
the plurality of straightening plates are inclined in a manner that angles made with the blowing port decrease from a location close to the blowing port in a width direction of the heat sink toward a distant location.

7. The cooling structure according to claim 6, wherein
the plurality of straightening plates become larger from a location close to the blowing port in a width direction of the heat sink toward a distant location.

8. The cooling structure according to claim 5 further comprising a housing arranged to cover the heat sink and taking in air from the air blowing part, wherein
the straightening plate is mounted on the housing.

9. The cooling structure according to claim 6, wherein
the plurality of straightening plates are extended from a blowing port of the air blowing part toward the heat sink, and
intervals between the plurality of straightening plates at the blowing port become smaller from a close location in a width direction of the heat sink toward a distant location.

10. An apparatus comprising:
a heat sink including a flat plate shaped base part and a plurality of fins erected on one surface of the base part, and at least part thereof includes an air guide region guiding air to at least an adjacent fin, at a location where air flows in;
a straightening plate guiding air from an air blowing part toward the heat sink, in the air guide region; and
a heating element transferring heat to a cooling structure.
